(19) United States
(12) Patent Application Publication
(10) Pub. No.: US 2021/0249554 A1
(43) Pub. Date: Aug. 12, 2021

(54) ULTRAVIOLET LIGHT-EMITTING DIODE AND METHOD OF MANUFACTURING THE SAME

(71) Applicant: EPILEDS TECHNOLOGIES, INC., Tainan City (TW)

(72) Inventors: Yen-Ting LU, Tainan City (TW); Che-Wei KUO, Tainan City (TW); Fu-Yi TSAI, Tainan City (TW); Wei-Pu ZHENG, Tainan City (TW); Kung-Hsieh HSU, Tainan City (TW); Ming-Sen HSU, Tainan City (TW)

(21) Appl. No.: 16/993,242

(22) Filed: Aug. 13, 2020

(30) Foreign Application Priority Data
Feb. 12, 2020 (TW) 109104412

(51) Int. Cl. H01L 33/00

(52) U.S. Cl. CPC H01L 33/0025; H01L 33/0075

(57) ABSTRACT

An ultraviolet light-emitting diode includes a transparent substrate and an ultraviolet illuminant epitaxial structure. The ultraviolet illuminant epitaxial structure includes an N-type semiconductor layer which is disposed on the transparent substrate and comprised of a first portion and a second portion. The first portion of the N-type semiconductor layer includes a light-emitting layer disposed thereon, a P-type semiconductor layer on the light emitting layer, and a P-type contact layer disposed on the P-type semiconductor layer. The second portion of the N-type semiconductor layer includes an N-type semiconductor film disposed thereon and separated from the light-emitting layer. A band gap of the N-type semiconductor film is smaller than a band gap of the light-emitting layer. The N-type contact is disposed on the N-type semiconductor film. The P-type contact is disposed on the P-type contact layer.

### RELATED APPLICATIONS

This application claims priority to Taiwan Application Serial Number 109104412, filed Feb. 12, 2020, which is herein incorporated by reference.

### BACKGROUND

### Field of Invention

The present invention relates to a light-emitting diode (LED), and more particularly, to an ultraviolet LED (UV LED).

### Description of Related Art

UV LEDs have attracted many attentions as UV LEDs applications are maturing in our daily lives such as air purification, water disinfection, and medical sterilizing. AlGaN is currently most common for producing UV LED. However, it is difficult to form contact electrodes having good Ohmic contact with semiconductor layers in an AlGaN based UV LED. Electrical and optical performance of the UV LED are thus hindered and there is room for improvement.

Thus, a manufacturing technique of an UV LED which can form contact electrodes having good Ohmic contact is needed for further improving luminous efficacy of the UV LED.

### SUMMARY

The objective of the present invention is to provide an UV LED structure and a method of manufacturing, that an N-type semiconductor film with an energy gap smaller than that of a light-emitting layer is formed on an exposed portion of an N-type semiconductor layer of an ultraviolet illuminant epitaxial structure. An N-type contact is subsequently formed on the N-type semiconductor film and performing superior Ohmic contact and lower electric resistance therebetween.

Another objective of the present invention is to provide an UV LED structure and a method of manufacturing, that the N-type contact does not require an alloying treatment or only requires a low temperature alloying treatment to complete the N-type contact forming process. It prevents the high temperature during alloying treatment from degrading other epitaxial layers.

To achieve aforementioned objectives, the present invention provides an UV LED including an N-type semiconductor layer having a first portion and a second portion on a transparent substrate. A light-emitting layer is disposed on the first portion of the N-type semiconductor layer, a P-type semiconductor layer is disposed on the light-emitting layer, and a P-type contact layer is disposed on the P-type semiconductor layer. An N-type semiconductor film is disposed on the second portion of the N-type semiconductor layer and is separated from the light-emitting layer, wherein an energy gap of the N-type semiconductor film is smaller than an energy gap of the light-emitting layer. An N-type contact is disposed on the N-type semiconductor film, and a P-type contact is disposed on the P-type contact layer.

In one embodiment of the present invention, the N-type semiconductor layer comprises Al_{y}Ga_{1-y}N, and y is between 0.55 and 0.65.

Optionally, a doping concentration of silicon of the N-type semiconductor film is greater than 1E18 1/cm³.

Optionally, the N-type semiconductor film includes GaN or GaInN.

Optionally, a thickness of the N-type semiconductor film ranges from 1 to 1,000 nm.

Optionally, the N-type contact comprises any one of Ti, Ni, Al, Pd, Rh, Pt, Au, and Cr, or an alloy thereof.

To achieve aforementioned objectives, the present invention further provides a manufacturing method of the UV LED. In this method, an ultraviolet illuminant epitaxial structure is formed on a transparent substrate. Forming of the ultraviolet illuminant epitaxial structure includes forming an N-type semiconductor layer on the transparent substrate, wherein the N-type semiconductor layer has a first portion and a second portion. A light-emitting layer, a p-type semiconductor layer, and a P-type contact layer are sequentially stacked on the first portion of the N-type semiconductor layer. An insulating protection layer is formed to cover the second portion of the N-type semiconductor layer, a top surface of the P-type contact layer, and side surfaces of the light-emitting layer, the P-type semiconductor layer, and the P-type contact layer. A portion of the insulating protection layer is removed to expose part of the second portion of the N-type semiconductor layer. An N-type semiconductor film is subsequently formed on the exposed part of the second portion of the N-type semiconductor layer, and is separated from the light-emitting layer, the P-type semiconductor layer, and the P-type contact layer, wherein an energy gap of the N-type semiconductor film is smaller than an energy gap of the light-emitting layer. A P-type contact is formed on the P-type contact layer, and an N-type contact is formed on the N-type semiconductor film.

In one embodiment of the present invention, forming of the N-type semiconductor film includes growing the N-type semiconductor film using metal-organic chemical vapor deposition (MOCVD) with a temperature ranging from 500 to 1,000 degrees Celsius, a pressure ranging from 30 to 1,000 mbar, and a doping concentration of silicon greater than 1E18 1/cm³.

In one embodiment of the present invention, the material of the insulating protection layer includes an oxide or a nitride. The oxide may be silicon dioxide (SiO₂) or aluminum oxide (Al₂O₃), and the nitride may be silicon nitride (SiN) or aluminum nitride (AlN).

Purposes, technical details and other features of the present invention will become readily apparent upon further review of the following embodiments and drawings.

### BRIEF DESCRIPTION OF THE DRAWINGS

FIG. 1 is a schematic cross-sectional view of an UV LED in accordance with one embodiment of the present invention;

FIGS. 2A to 2D are schematic cross-sectional views of various stages showing a process for manufacturing an UV LED in accordance with one embodiment of the present invention; and

FIG. 3 is a schematic cross-sectional view of a transparent substrate in accordance with one embodiment of the present invention.

### DETAILED DESCRIPTION

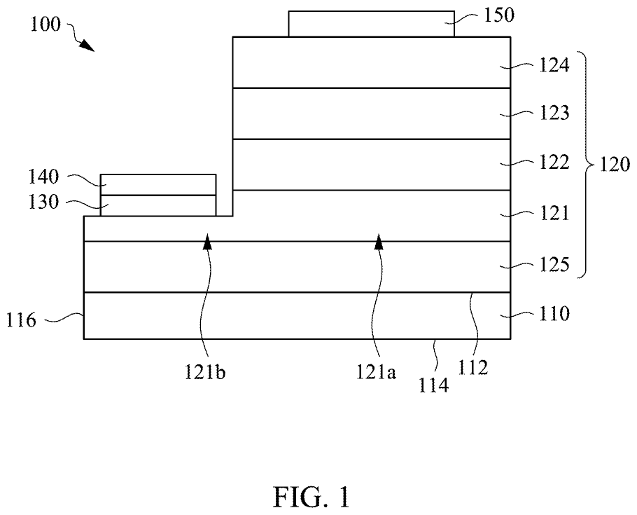

Referring to FIG. 1, a schematic cross-sectional view of an UV LED in accordance with one embodiment of the present invention. An UV LED 100 may emit ultraviolet light having a wavelength ranging from 100 to 400 nm. For example, the UV LED 100 may be an UVA LED having a light emission wavelength ranging from 320 to 400 nm, an UVB LED having a light emission wavelength ranging from 280 to 320 nm, or an UVC LED having a light emission wavelength ranging from 100 to 280 nm. The UV LED 100 includes a transparent substrate 110, an ultraviolet illuminant epitaxial structure 120, an N-type semiconductor film 130, an N-type contact 140, and a P-type contact 150.

The transparent substrate 110 includes a first surface 112, a second surface 114, and several side surfaces 116, wherein the first surface 112 and the second surface 114 are respectively located on two opposite sides of the transparent substrate 110, and the side surfaces 116 surround and are disposed between the first surface 112 and the second surface 114. A material of the transparent substrate 110 may be, for example, sapphire, aluminum nitride, or silicon carbide.

As shown in FIG. 1, the ultraviolet illuminant epitaxial structure 120 is disposed on the first surface 112 of the transparent substrate 110. In some embodiments, the ultraviolet illuminant epitaxial structure 120 includes an N-type semiconductor layer 121, a light-emitting layer 122, a p-type semiconductor layer 123, and a P-type contact layer 124. The N-type semiconductor layer 121 is disposed on the first surface 112 of the transparent substrate 110 and includes a first portion 121a and a second portion 121b. The ultraviolet illuminant epitaxial structure 120 may selectively include a buffer layer 125 located between the transparent substrate 110 and the N-type semiconductor 121 to reduce epitaxial defects in the N-type semiconductor layer 121. The light-emitting layer 122 is disposed on the first portion 121a of the N-type semiconductor layer 121. The light-emitting layer 122 emits ultraviolet light. In some embodiments, the light-emitting layer 122 may include a multiple quantum well (MQW) structure. The P-type semiconductor layer 123 is located on the light-emitting layer 122, such that the light-emitting layer 122 is sandwiched between the P-type semiconductor layer 123 and the first portion 121a of the N-type semiconductor layer 121. The P-type contact layer 124 is disposed on the P-type semiconductor layer 123.

A material of the N-type semiconductor layer 121 may include N-type Al_{y}Ga_{1-y}N, a material of the light-emitting layer 122 may include Al_{z}Ga_{1-z}N, a material of the P-type semiconductor layer 123 may include P-type AlGaN, a material of the P-type contact layer 124 may include P-type GaN, and a material of the buffer layer 125 may include AlN. When the UV LED 100 is a flip chip type UVB LED or UVC LED where the light emitting wavelength is lower than 320 nm, an aluminum content of N-type Al_{y}Ga_{1-y}N of the N-type semiconductor layer 121 is typically greater than that of Al_{z}Ga_{1-z}N of the light-emitting layer 122, i.e. y>z, wherein y is between 0.55 and 0.65 in this embodiment. In some embodiments, the ultraviolet illuminant epitaxial structure 120 may also include a superlattice structure (not shown) located between the buffer layer 125 and the N-type semiconductor layer 121.

Still referring to FIG. 1, the N-type semiconductor film 130 is disposed on the second portion 121b of the N-type semiconductor layer 121, and separated from the light-emitting layer 122, the P-type semiconductor layer 123, and the P-type contact layer 124. A thickness of the N-type GaN film 130 may range from 1 to 1,000 nm. An energy gap of the N-type semiconductor film 130 is smaller than that of the light-emitting layer 122, and the energy gap of the light-emitting layer 122 is smaller than that of the N-type semiconductor layer 121. In this embodiment, the N-type semiconductor film 130 is an N-type AlₓGa₁₋ₓN film. The N-type semiconductor layer 121, the light-emitting layer 122, and the P-type semiconductor layer 123 all include AlGaN, and an aluminum content of the AlₓGa₁₋ₓN of the N-type semiconductor film 130 is smaller than an aluminum content of the AlₓGa₁₋ₓN of the light-emitting layer 122, i.e. z>x. In other embodiments, a material of the N-type semiconductor film 130 includes GaN and GaInN.

The N-type contact 140 is disposed on the N-type semiconductor film 130. The N-type contact 140 may include any one of Ti, Ni, Al, Pd, Rh, Pt, Au, and Cr, or an alloy thereof. In some exemplary embodiments, the N-type contact 140 may be a Ti/Al/Ti/Au stacked structure, a Cr/Pt/Au stacked structure, or a Cr/Al/Ti/Au stacked structure, wherein the Au films are located at tops of the stacked structures respectively. The P-type contact 150 is disposed on a portion of the P-type contact layer 124. A material of the P-type contact 150 may be metal. The N-type contact 140 and the p-type contact 150 may also be respectively referred to an N-type contact metal layer and a P-type contact metal layer.

By growing the N-type semiconductor film 130 with the energy gap smaller than that of the light-emitting 122 on the exposed part of the second portion 121b of the N-type semiconductor layer 121, the N-type contact 140 on the N-type semiconductor film 130 performs superior Ohmic contact and low electric resistance.

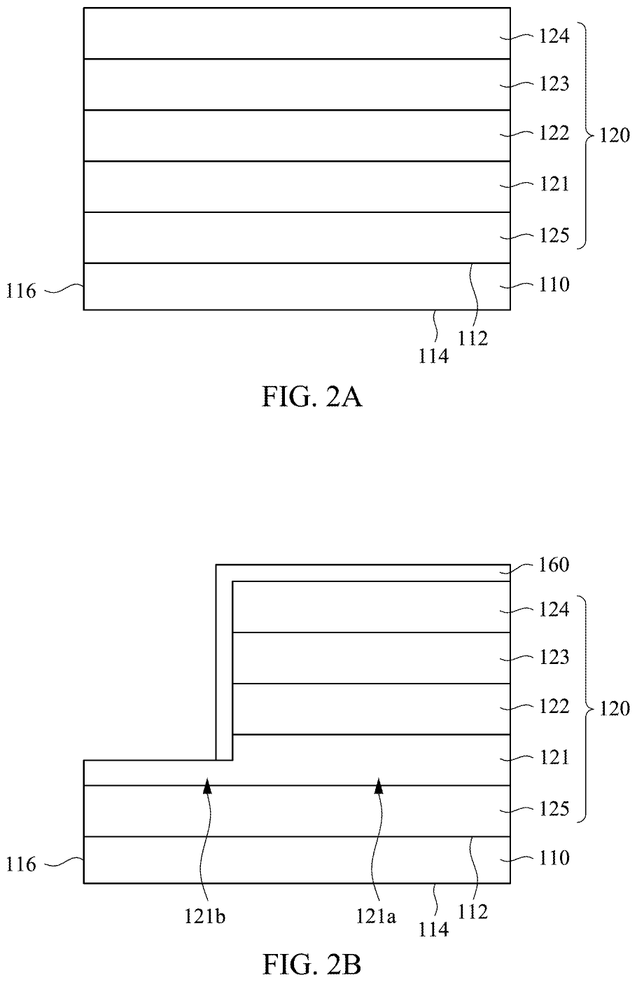

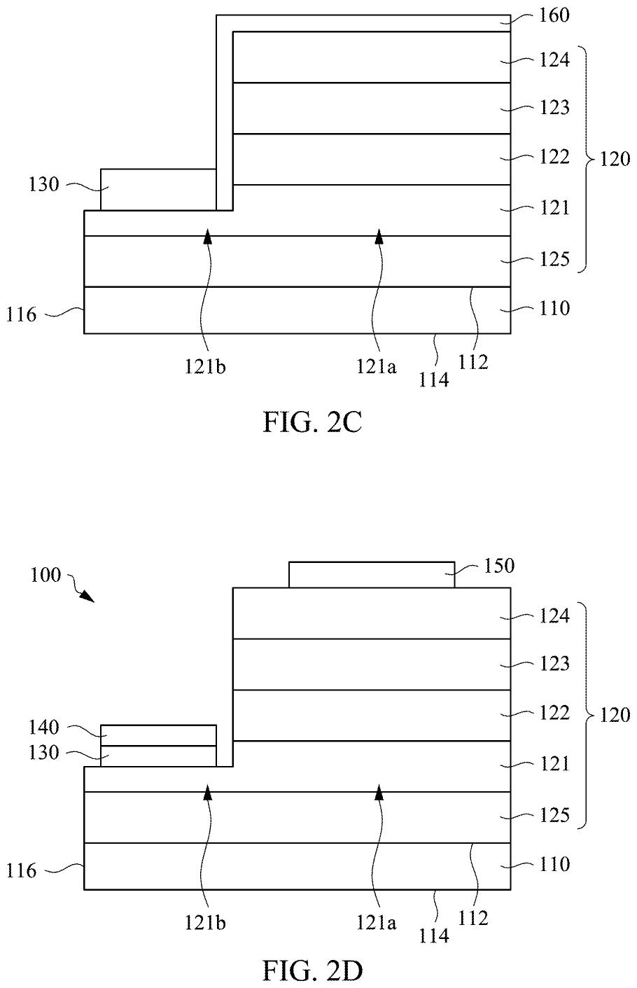

Referring to FIGS. 2A to 2D, schematic cross-sectional views of various stages showing a process for manufacturing the UV LED in accordance with one embodiment of the present invention. A transparent substrate 110 may be provided first, and the ultraviolet illuminant epitaxial structure 120 is formed on the first surface 112 of the transparent substrate 110 by, for example, MOCVD. As shown in FIG. 2A, forming of the ultraviolet illuminant epitaxial structure 120 includes forming the buffer layer 125 on the first surface 112 of the transparent substrate 110, the N-type semiconductor layer 121 on the buffer layer 125, the light-emitting layer 122 on the N-type semiconductor layer 121, the P-type semiconductor layer 123 on the light-emitting layer 122, and the P-type contact layer 124 on the P-type semiconductor layer 123.

As shown in FIG. 2B, after the ultraviolet illuminant epitaxial structure 120 is completed, a portion of the N-type semiconductor layer 121, a portion of the light-emitting layer 122, a portion of the P-type semiconductor layer 123, and a portion of the P-type contact layer 124 of the ultraviolet illuminant epitaxial structure 120 are removed by using, for example, a photolithograph and etching process, to expose portions of the N-type semiconductor layer 121, light-emitting layer 122, P-type semiconductor layer 123, and the P-type contact layer 124, wherein the exposed portion of the N-type semiconductor layer 121 is the second portion 121b of the N-type semiconductor layer 121. That is, the N-type semiconductor layer 121, the light-emitting layer 122, the P-type semiconductor layer 123, and the P-type contact layer 124 above the second portion 121b of the N-type semiconductor layer 121 are removed. The N-type semiconductor layer 121, the light-emitting layer 122, the P-type semiconductor layer 123, and the P-type contact layer 124 above the first portion 121a of the N-type semiconductor layer 121 are kept.

Still referring to FIG. 2B, an insulating protection layer 160 is formed to cover the exposed portions of the N-type semiconductor layer 121, the light-emitting layer 122, the P-type semiconductor layer 123, and the P-type contact layer 124 by using, for example, a plasma-enhanced CVD (PECVD) process. That is the insulating protection layer 160 covers the top surface of the second portion 121b of the N-type semiconductor layer 121, the top surface of the P-type contact layer 124, as well as side surfaces of the light-emitting layer 122, P-type semiconductor layer 123, and P-type contact layer 124. The material of the insulating protection layer 160 may include an oxide or a nitride, wherein the oxide may be silicon dioxide (SiO₂) or aluminum oxide (Al₂O₃), and the nitride may be silicon nitride (SiN) or aluminum nitride (AlN). A portion of the insulating protection layer 160 is removed by using, for example, a photolithograph and etching process to expose a part of the second portion 121b of the N-type semiconductor layer 121, while other surfaces remain covered.

Subsequently, as shown in FIG. 2C, the N-type semiconductor film 130 is formed on the exposed part of the second portion 121b of the N-type semiconductor layer 121. With the protection and separation of the insulating protection layer 160, the N-type semiconductor film 130 is formed separately from the light-emitting layer 122, P-type semiconductor layer 123, and P-type contact layer 124. The energy gap of the N-type semiconductor film 130 is smaller than an energy gap of the light-emitting layer 122. In some exemplary embodiments, the material of the N-type semiconductor film 130 may include GaN, GaInN, or AlGaN having aluminum contents smaller than that of the AlGaN of the light-emitting layer 122.

The N-type semiconductor film 130 may be grown by using MOCVD, CVD, hydride vapor phase epitaxy (HVPE), or sputtering process. In addition, dopants of the N-type semiconductor film 130 may include silicon, germanium, and oxygen. In some embodiments, forming of the N-type semiconductor film 130 includes growing the N-type semiconductor film 130 by MOCVD, wherein the growth temperature is controlled between 500 and 1,000 degree Celsius, the growth pressure is controlled between 30 and 1,000 mbar, and the doping concentration of silicon is greater than 1E18 1/cm³.

After the N-type semiconductor film 130 is completed, the insulating protection layer may be removed by using, for example, an etching process. Then, as shown in FIG. 2D, the N-type contact 140 may be formed on the N-type semiconductor film 130 by, for example, an evaporation process. Similarly, the P-type contact 150 may be formed on the P-type contact layer 124 by, for example, an evaporation process, to complete the manufacturing of the UV LED 100.

In aforementioned embodiments, the N-type contact 140 on the N-type semiconductor film 130 performs superior Ohmic contact and low electric resistance, and the N-type contact 140 does not require an alloying treatment or only requires a low temperature alloying treatment under 500 degree Celsius after being formed. Therefore, it prevents degrading the quality of other epitaxial layers caused by the high temperature during alloying treatment.

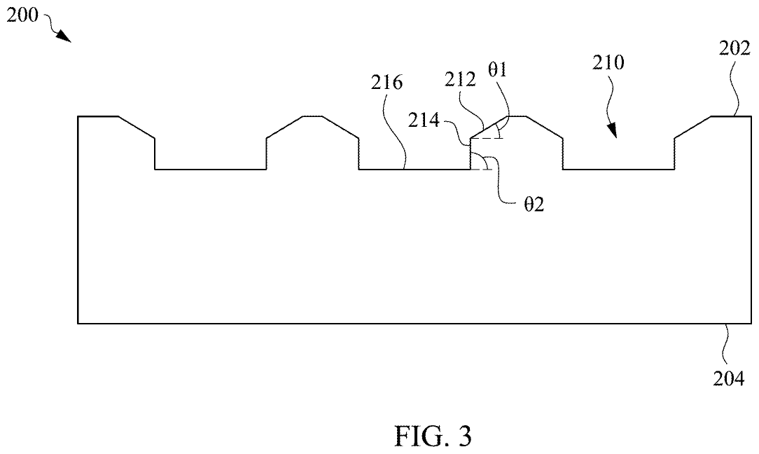

Referring to FIG. 3, a schematic cross-sectional view of a transparent substrate in accordance with one embodiment of the present invention. An alternative transparent substrate 200 may be used instead of the transparent substrate 100 in aforementioned embodiments. The material of the transparent substrate 200 may be, for example, sapphire, aluminum nitride, or silicon carbide. The transparent substrate 200 includes a first surface 202 and an opposite second surface 204. The ultraviolet illuminant epitaxial structure 120 may be grown on the first surface 202 of the transparent substrate 200. The first surface 202 of the transparent substrate 200 is arranged with a plurality of cavities 210.

As shown in FIG. 3, the cavities 210 may be separated from each other and repeated with a predetermined pitch, i.e. periodically arranged. For example, the predetermined pitch may be from about 0.5 to 5 μm. In some embodiments, each of the cavities 210 includes a first inclined surface 212, a second inclined surface 214, and a bottom surface 216 adjacent and connected sequentially. The first inclined surface 212 has a first angle θ1 with respect to the bottom surface 216, and the second inclined surface 214 has a second angle θ2 with respect to the bottom surface 216, wherein the first angle 91 is different from the second angle θ2. In some exemplary embodiments, the first angle 91 is smaller than the second angle θ2. For example, the first angle θ1 may be from about 30 to 90 degrees, and the second angle θ2 may be from about 75 to 90 degrees.

By periodically arranging the cavities 210 with varied angles on the first surface 202 of the transparent substrate 200, air gaps (not shown) are periodically formed along the cavities 210 during the growing of buffer layer 125. These air gaps provides further buffering characteristics and improves the quality of the ultraviolet illuminant epitaxial structure 120 grown on the first surface 202, thereby increases yield rate of production and leading to reduce manufacturing cost.

Still referring to FIG. 1, in some embodiments, a transparent structure may be disposed on the second surface 114 of the transparent substrate 110 of the UV LED 100, wherein a refractive index of the transparent structure is between a refractive index of the transparent substrate and a refractive index of air. The transparent structure may enhance refraction of light inside the UV LED to increase light extraction of the UV LED. The transparent structure may be a single-layered structure or a structure formed by stacking various films. The transparent structure may have a constant refractive index, or a gradient refractive index that the refractive index is decremented from the second surface 114 of the transparent substrate 110 towards the transparent structure. When the transparent structure is formed by stacking various films, the films may combine various thicknesses and refractive indexes accordingly to optimize generation conditions of UV light.

In other embodiments, the second surface 114 of the transparent substrate 100 may be disposed with various three-dimensional structures to reduce total internal reflection of light inside the UV LED, so that light extraction efficiency of the UV LED is further enhanced.

In further other embodiments, longitudinally arranged stealth dicing marks are formed on the side surfaces 116 of the transparent substrate 110 during a laser stealth dicing to increase roughness of the side surfaces 116 of the transparent substrate 110, thereby enhancing lateral light extraction efficiency of the UV LED.

In yet other embodiments, a thickness of the transparent substrate may be increased to make a height of the UV LED greater than its length and/or width, so that a lateral light extraction area of the UV LED is increased, thereby further enhancing overall light extraction of the UV LED.

According to aforementioned embodiments, one advantage of the present invention is that an N-type semiconductor film with an energy gap smaller than that of a light-emitting layer grown on an exposed portion of an N-type semiconductor layer of an ultraviolet illuminant epitaxial structure, such that an N-type contact formed on the N-type semiconductor film performs superior Ohmic contact and lower electric resistance.

Another advantage of the present invention is that the N-type contact does not require an alloying treatment or only requires a low temperature alloying treatment after the N-type contact is formed, such that it can prevent the high temperature during alloying treatment from degrading quality of other epitaxial layers.

Although the present invention has been described in considerable details with reference to certain embodiments, the foregoing embodiments of the present invention are illustrative of the present invention rather than limiting of the present invention. It will be apparent to those having ordinary skill in the art that various modifications and variations can be made to the present invention without departing from the scope or spirit of the invention. Therefore, the spirit and scope of the appended claims should not be limited to the description of the embodiments contained herein.

What is claimed is:

1. An ultraviolet light-emitting diode, comprising:
a transparent substrate;
an N-type semiconductor layer disposed on the transparent substrate, wherein the N-type semiconductor layer has a first portion and a second portion;
a light-emitting layer, a P-type semiconductor layer, a P-type contact layer, and a P-type contact sequentially stacked on the first portion of the N-type semiconductor layer;
an N-type semiconductor film disposed on the second portion of the N-type semiconductor layer and separated from the light-emitting layer, wherein the N-type semiconductor film and the light-emitting layer both comprise AlGaN, and an aluminum content the AlGaN of the N-type semiconductor film is smaller than an aluminum content of the AlGaN of the light-emitting layer; and
an N-type contact disposed on the N-type semiconductor film.

2. The ultraviolet light-emitting diode of claim 1, wherein the N-type semiconductor layer comprises Al_{y}Ga_{1-y}N, and y is between 0.55 and 0.65.

3. The ultraviolet light-emitting diode of claim 1, wherein a doping concentration of silicon of the N-type semiconductor film is greater than 1E18 1/cm³.

4. The ultraviolet light-emitting diode of claim 1, wherein the N-type semiconductor film comprises GaInN.

5. The ultraviolet light-emitting diode of claim 1, wherein a thickness of the N-type semiconductor film ranges from 1 to 1,000 nm.

6. The ultraviolet light-emitting diode of claim 1, wherein the N-type contact comprises any one of Ti, Ni, Al, Pd, Rh, Pt, Au, and Cr, or an alloy thereof.

7. An ultraviolet light-emitting diode, comprising:
a transparent substrate;
an N-type semiconductor layer disposed on the transparent substrate, wherein the N-type semiconductor layer has a first portion and a second portion;
a light-emitting layer, a P-type semiconductor layer, a P-type contact layer, and a P-type contact stacked on the first portion of the N-type semiconductor layer sequentially;
an N-type semiconductor film disposed on the second portion of the N-type semiconductor layer and separated from the light-emitting layer, wherein an energy gap of the N-type semiconductor film is smaller than an energy gap of the light-emitting layer; and
an N-type contact disposed on the N-type semiconductor film.

8. The ultraviolet light-emitting diode of claim 7, wherein the N-type semiconductor layer, the light-emitting layer, the P-type semiconductor layer, and the N-type semiconductor film all comprise AlGaN, and an aluminum content of the AlGaN of the N-type semiconductor film is smaller than an aluminum content of the light-emitting layer.

9. The ultraviolet light-emitting diode of claim 7, wherein a doping concentration of silicon of the N-type semiconductor film is greater than 1E18 1/cm³.

10. The ultraviolet light-emitting diode of claim 7, wherein the N-type semiconductor film comprises GaN or GaInN.

11. The ultraviolet light-emitting diode of claim 7, wherein a thickness of the N-type semiconductor film ranges from 1 to 1,000 nm.

12. The ultraviolet light-emitting diode of claim 7, wherein the N-type contact comprises any one of Ti, Ni, Al, Pd, Rh, Pt, Au, and Cr, or an alloy thereof.

13. A method of manufacturing an ultraviolet light-emitting diode, comprising:
forming an ultraviolet illuminant epitaxial structure on a transparent substrate, wherein forming of the ultraviolet illuminant epitaxial structure comprises:
forming an N-type semiconductor layer on the transparent substrate, wherein the N-type semiconductor layer has a first portion and a second portion; and
forming a light-emitting layer, a p-type semiconductor layer, and a P-type contact layer on the first portion of the N-type semiconductor layer sequentially;
forming an insulating protection layer to cover the second portion of the N-type semiconductor layer, a top surface of the P-type contact layer, and side surfaces of the light-emitting layer, the P-type semiconductor layer, and the P-type contact layer;
removing a portion of the insulating protection layer to partially expose the second portion of the N-type semiconductor layer;
forming an N-type semiconductor film on the exposed second portion of the N-type semiconductor layer and separated from the light-emitting layer, the P-type semiconductor layer, and the P-type contact layer, wherein an energy gap of the N-type semiconductor film is smaller than an energy gap of the light-emitting layer;
forming a P-type contact on the P-type contact layer; and
forming an N-type contact on the N-type semiconductor film.

14. The method of claim 13, wherein the N-type semiconductor layer, the light-emitting layer, the P-type semiconductor layer, and the N-type semiconductor film all comprise AlGaN, and an aluminum content of the AlGaN of the N-type semiconductor film is smaller than an aluminum content of the light-emitting layer.

15. The method of claim 13, wherein the N-type semiconductor film comprises GaN and GaInN.

16. The method of claim 13, wherein forming the N-type semiconductor film comprises growing the N-type semiconductor film by using a metal-organic chemical vapor deposition (MOCVD) process, with a temperature of the N-type semiconductor film ranging from 500 to 1,000 degrees Celsius, a pressure ranging from 30 to 1,000 mbar, and a doping concentration of silicon of the N-type semiconductor film greater than 1E18 1/cm³.

17. The method of claim 13, wherein a thickness of the N-type semiconductor film ranging from 1 to 1,000 nm.

18. The method of claim 13, wherein a material of the insulating protection layer comprises an oxide or a nitride, the oxide is silicon dioxide (SiO₂) or aluminum oxide (Al₂O₃), and the nitride is silicon nitride (SiN) or aluminum nitride (AlN).

19. The method of claim 13, wherein the N-type contact comprises any one of Ti, Ni, Al, Pd, Rh, Pt, Au, and Cr, or an alloy thereof.

20. The method of claim 13, wherein the N-type contact comprises a Ti/Al/Ti/Au stacked structure, a Cr/Pt/Au stacked structure, or a Cr/Al/Ti/Au stacked structure.
